(19) United States
(12) Patent Application Publication
(10) Pub. No.: US 2010/0078063 A1
(43) Pub. Date: Apr. 1, 2010

(54) HIGH EFFICIENCY HYBRID SOLAR CELL

(76) Inventors: Allen M. Barnett, Landenberg, PA (US); Christiana Beatrice Honsberg, Tempe, AZ (US); Stuart Graham Bowden, Tempe, AZ (US)

Correspondence Address: POTTER ANDERSON & CORROON LLP;ATTN: JANET E. REED, PH.D., P.O. BOX 951, WILMINGTON, DE, 19899-0951, US

(21) Appl. No.: 12/568,213

(22) Filed: Sep. 28, 2009

Related U.S. Application Data
(63) Continuation-in-part of application No. PCT/US2008/009732, filed on Aug. 14, 2008.
(60) Provisional application No. 61/194,598, filed on Sep. 29, 2008.
(60) Provisional application No. 60/966,792, filed on Aug. 29, 2007.

(51) Int. Cl. H01L 31/052

(52) U.S. Cl. 136/246

(57) ABSTRACT

This invention relates to a high efficiency hybrid solar cell preferably comprised of a static concentrator, a dichroic mirror, a first cell stack comprising two cells, the first cell being a GaInP cell and the second cell being a GaAs cell and a second cell stack comprising three cells, the first cell being a Si cell, the second cell being a GaInAsP cell and the third cell being a GaInAs cell. The dichroic mirror provides a separation of the solar light into two spectral components, one component of light with photons of energy≧E_{g} that impinges upon the first cell stack and one component of light with photons of energy<E_{g} that impinges upon the second cell stack.

### CROSS-REFERENCE TO RELATED APPLICATIONS

This application claims the benefit of U.S. Provisional Application No. 61/194,598, filed Sep. 29, 2008, and is a continuation-in-part of International Application No. PCT/US2008/009732, filed Aug. 14, 2008, which claims the benefit of U.S. Provisional Application No. 60/966,792, filed Aug. 29, 2007, all of which are incorporated by reference in their entireties.

This invention was made with Government support under Agreement W911NF-05-9-0005 awarded by the Government. The Government has certain rights in the invention.

The invention claimed herein was made pursuant to the Articles of Collaboration for the 50% Efficient Solar Cells Consortium formed pursuant to the Defense Advanced Research Projects Agency (DARPA) award to the University of Delaware Oct. 1, 2005, W911NF-05-9.0005.

### FIELD OF THE INVENTION

This invention relates to a high efficiency hybrid solar cell suitable for use in both mobile and stationary applications.

### BACKGROUND OF THE INVENTION

Solar cell development has been in progress for over fifty years. One-junction silicon solar cells have received much attention over that period and are used in terrestrial photovoltaic applications. However, a one-junction silicon solar cell captures less than half of the theoretical potential for solar energy conversion with the best laboratory solar cells currently providing only about 24.7% efficiency. This limits the application of such cells.

High performance photovoltaic systems are required for both economic and technical reasons. The cost of electricity can be halved by doubling the efficiency of the solar cell. Many applications do not have the area required to provide the needed power using current solar cells.

Two types of solar cell architecture have been proposed for more efficient solar cells. One is a lateral architecture. An optical dispersion element is used to split the solar spectrum into its wavelength components. Separate solar cells are placed under each wavelength band component and the cells are chosen so that they provide good efficiency for light of that wavelength band component. Another architecture is a vertical one in which individual solar cells with different energy gaps are arranged in a stack. These are commonly referred to as cascade, tandem or multiple junction cells. The solar light is passed through the stack.

There is a need for the development of higher efficiency solar cells and an architecture that enables the achievement of such solar cells.

### SUMMARY OF THE INVENTION

This invention provides a high efficiency hybrid solar cell comprising 1) a means for separating light into more than one spectral component based upon energy of the photons of light, and 2) at least two individual cells or cell stacks, at least one of which is a cell stack comprising more than one individual cell.

Preferably, the invention further provides the above-described high efficiency hybrid solar cell comprising a concentrating optical element, most preferably a static concentrating optical element, that serves to concentrate the solar light that will be directed to the light separating means.

More preferably, the invention provides a high efficiency hybrid solar cell comprising:

(a) a dichroic mirror operating at E_{g} and positioned so that solar light impinges upon the dichroic mirror, wherein the dichroic mirror provides a separation of the solar light into two spectral components, one component of light with photons of energy≧E_{g} and one component of light with photons of energy<E_{g}, wherein one of these components is reflected by the dichroic mirror and one is transmitted by the dichroic mirror;

(b) a first cell stack comprising two cells, the first cell being a GaInP cell and the second cell being a GaAs cell, arranged vertically in descending order of their energy gaps with the first cell having the larger energy gap of the cells in the first cell stack, the first cell stack being positioned so that the component of light with photons of energy≧E_{g} impinges upon the surface of the first cell in the first cell stack, wherein the cells in the first cell stack each absorb light with photons of energy greater than or equal to their energy gap and are transparent to and transmit light with photons of energy less than their energy gap, wherein E_{g} is equal to about the energy gap of the GaAs cell; and

(c) a second cell stack comprising three cells, the first cell being a silicon cell, the second cell being a GaInAsP cell and the third cell being a GaInAs cell, arranged vertically in descending order of their energy gaps with the first cell having the largest energy gap of the cells in the second cell stack, the second cell stack being positioned so that the component of light with photons of energy<E_{g} impinges upon the surface of the first cell in the second cell stack, wherein the energy gap of each cell in the second cell stack is <E_{g} and wherein cells in the second cell stack each absorb light with photons of energy greater than or equal to their energy gap and are transparent to and transmit light with photons of energy less than their energy gap.

Most preferably, the invention provides a high efficiency hybrid solar cell comprising:

(a) a dichroic mirror operating at E_{g} and positioned so that solar light impinges upon the dichroic mirror, wherein the dichroic mirror provides a separation of the solar light into two spectral components, one component of light with photons of energy≧E_{g} and one component of light with photons of energy<E_{g}, wherein one of these components is reflected by the dichroic mirror and one is transmitted by the dichroic mirror;

(b) a first cell stack comprising two cells, the first cell being a GaInP cell and the second cell being a GaAs cell, arranged vertically in descending order of their energy gaps with the first cell having the larger energy gap of the cells in the first cell stack, the first cell stack being positioned so that the component of light with photons of energy≧E_{g} impinges upon the surface of the first cell in the first cell stack, wherein the cells in the first cell stack each absorb light with photons of energy greater than or equal to their energy gap and are transparent to and transmit light with photons of energy less than their energy gap, wherein E_{g} is equal to about the energy gap of the GaAs cell; and

(c) a second cell stack comprising three cells, the first cell being a silicon cell, the second cell being a GaInAsP cell and the third cell being a GaInAs cell, arranged vertically in descending order of their energy gaps with the first cell having the largest energy gap of the cells in the second cell stack, the second cell stack being positioned so that the component of light with photons of energy<E_{g} impinges upon the surface of the first cell in the second cell stack, wherein the energy gap of each cell in the second cell stack is <E_{g} and wherein cells in the second cell stack each absorb light with photons of energy greater than or equal to their energy gap and are transparent to and transmit light with photons of energy less than their energy gap; and

(d) a static concentrating optical element that directs solar light to the dichroic mirror (a).

Other preferred embodiments include wherein the dichroic mirror is a “cold” dichroic mirror. Further, the individual cells or cell stacks preferably comprise different solar cell active areas, which leads to different levels of concentration of sunlight impinging upon the cells or cell stacks.

### BRIEF DESCRIPTION OF THE FIGURES

FIG. 1 shows a schematic drawing of a cell stack.

FIGS. 2A and 2B show a design of a silicon cell useful in the present invention.

FIG. 3 illustrates an embodiment of the hybrid solar cell with a dichroic mirror that reflects light with photons of energy≧E_{g} and transmits light with photons of energy<E_{g} and with two cell stacks placed orthogonally within the solar cell.

FIG. 4 illustrates another embodiment of the hybrid solar cell with a dichroic mirror that reflects light with photons of energy≧E_{g} and transmits light with photons of energy<E_{g} and with two cell stacks in a coplanar configuration.

FIG. 5 illustrates another embodiment of the hybrid solar cell with a dichroic mirror that reflects light with photons of energy≧E_{g} and transmits light with photons of energy<E_{g} and with two cell stacks in a coplanar configuration.

### DETAILED DESCRIPTION OF THE PREFERRED EMBODIMENTS

Unless otherwise stated, all references cited are hereby specifically incorporated by reference. Further, when an amount, concentration, or other value or parameter is given either as a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

As used herein, the articles “a”, “an”, and “the” preceding an element or component of the invention are intended to be nonrestrictive regarding the number of instances (i.e., occurrences) of the element or component. Therefore “a”, “an” and “the” should be read to include one or at least one, and the singular word form of the element or component also includes the plural unless the number is obviously meant to be singular.

As used herein, the term “comprising” means the presence of the stated features, integers, steps, or components as referred to in the claims, but does not preclude the presence or addition of one or more other features, integers, steps, components or groups thereof. The term “comprising” is intended to include embodiments encompassed by the terms “consisting essentially of” and “consisting of”. Similarly, the term “consisting essentially of” is intended to include embodiments encompassed by the term “consisting of”.

The instant invention provides a high efficiency hybrid solar cell with efficiency in excess of 30% and, preferably, up to and surpassing 40%. The hybrid solar cell is comprised of a means for separating light into more than one spectral component based upon energy of the photons of light, preferably a dichroic mirror, and at least two individual cells or cell stacks, at least one of which is a cell stack, preferably a first cell stack comprising a GaInP cell and a GaAs cell and a second cell stack comprising a Si cell, a GaInAsP cell and a GaInAs cell. In a preferred embodiment, the hybrid solar cell also comprises an optical concentrator, most preferably a static optical concentrator, positioned so that solar light concentrated thereby impinges upon the light separating means.

The means for separating light into more than one spectral component, or light separating means, may comprise any optical element system capable of splitting light on the basis of wavelength, such as a prism, a grating element, a filter, or preferably a dichroic mirror. Most preferably, the light separating means is a dichroic mirror operating at E_{g} that is positioned so that the solar light impinges upon the dichroic mirror. In one embodiment, the dichroic mirror is a so-called “cold” dichroic mirror that reflects light with photons of energy≧E_{g} and transmits light with photons of energy<E_{g}. Another embodiment entails use of a so-called “hot” dichroic mirror, that transmits light with photons of energy≧E_{g} and reflects light with photons of energy<E_{g}. The dichroic mirror can be planar or curved, and can be positioned within the solar cell at a variety of angles with respect to the concentrating means, and with respect to the cells and cell stacks, thus enabling a variety of configurations within the solar cell unit for placement of the individual cells and cell stacks.

“Cell” is used herein to describe the individual cells placed individually within the solar cell unit, or stacked together to form a cell stack within the solar cell unit. The term “solar cell” or “solar cell” unit is used herein to describe the complete device.

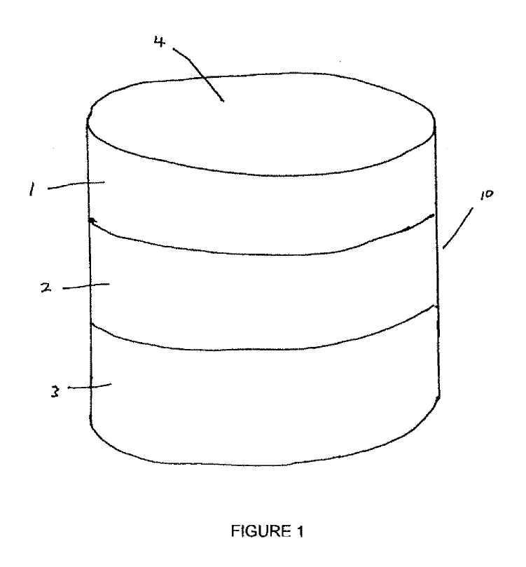

As indicated above, as used herein “arranged vertically in descending order of their energy gaps with the first cell having the largest energy gap of the cells in the stack” means that the cells in a stack are arranged sequentially with the first cell having the largest energy gap, the second cell directly below the first cell having the next largest energy gap, the third cell directly below the second cell having the third largest energy gap, etc. This arrangement of a cell stack is shown schematically in FIG. 1. The cell stack 10 has three cells, 1, 2 and 3, with cell 1 being the first cell. The energy gaps of the three cells are such that E_{g}¹>E_{g}²>E_{g}³ where E_{g}¹ is the energy gap of cell 1, E_{g}² is the energy gap of cell 2 and E_{g}³ is the energy gap of cell 3. Cell 1 will absorb the light with photons of energy≧E_{g}¹ and transmit the light with photons of energy<E_{g}¹. Cell 2 will absorb the light with photons of energy≧E_{g}² and transmit the light with photons of energy<E_{g}². Similarly with cell 3. The cells can be thought of as being in series optically. The cells convert the energy of the absorbed photons into electricity.

“Absorbed” as used herein means that a photon absorbed by the cell results in the creation of an electron-hole pair. “The dichroic mirror operating at E_{g}” is used herein to mean that the dichroic mirror provides a separation of the solar light into two spectral components, one component of light with photons of energy≧E_{g} and one component of light with photons of energy<E_{g}. One of these components is reflected by the dichroic mirror and one is transmitted by the dichroic mirror. A “cold” dichroic mirror reflects light with photons of energy≧E_{g} and transmits light with photons of energy<E_{g} and a “hot” dichroic mirror transmits light with photons of energy≧E_{g} and reflects light with photons of energy<E_{g}. Typically the dichroic mirror will be positioned so that it is not perpendicular to the solar light. In this way the direction of the reflected light is not directly back toward the incoming solar light but is rather at an angle with respect to the direction of the solar light impinging on the dichroic mirror and the reflected light can more readily be arranged to impinge upon the appropriate cell stack. The transition from transmission to reflection occurs over a range of energies and corresponding wavelengths. The operating energy E_{g} is taken as the midpoint of this transition region. For example, for a “cold” dichroic mirror, unless the transition is extremely sharp, it is recognized that some photons of energy>E_{g} will be transmitted and some photons of energy<E_{g} will be reflected. In the transition range, the majority of photons with energies greater than E_{g} are reflected; the majority of photons with energies less than E_{g} are transmitted. The above definition of “the dichroic mirror operating at E_{g}” should be understood and interpreted in terms of this recognition of the nature of the transition region. For a given dichroic mirror, the operating energy shifts to lower energies (higher wavelengths) as the dichroic mirror is rotated away from being perpendicular to the direction of incidence of the light beam impinging upon it and “the dichroic mirror operating at E_{g}” should be understood and interpreted to apply to the position in which the dichroic mirror is placed relative to the direction of the impinging light. A dichroic mirror is a multilayer structure, typically containing 20 or more alternate layers of two transparent oxides. A sharper transition requires more layers and higher cost.

“Hybrid” is used herein to describe the instant solar cell indicating that it contains at least two cells or cell stacks designed to capture different wavelength band components (which can be at least in part overlapping), at least one of which is a cell stack.

In a preferred embodiment, the high efficiency solar cell further comprises a concentrating optical element, most preferably a static concentrating optical element. The intensity or concentration of solar radiation striking a surface is 1×, the normal concentration. It is more difficult and more expensive to achieve high solar cell efficiency with 1× solar light than it is using solar light of higher concentrations. The purpose of the optical concentrating element is to collect and concentrate the light impinging upon it and concentrate and direct such light to the surface of the light separating means, e.g. a dichroic mirror. The concentrating optical element therefore increases the power density of the light that ultimately is directed to the cells, i.e., increases the concentration to n× where n is greater than 1. This increases the power density of the portion of the total solar light that can be utilized by the individual cells. In a preferred embodiment, the cells or cell stacks will have different active areas onto which the light is directed, thus causing different concentrations of sunlight on the different cell stacks. The performance of these cells or cell stacks can thereby be individually improved and overall solar cell module efficiency is increased.

“Concentration of sunlight” as used herein is defined as the area of the aperture collecting the sunlight divided by a cell or cell stack active surface area. Only the photons in the spectral band directed to a given solar cell impinge upon it. All those impinging photons impinge upon the area of the aperture. The concentration for the spectral band is therefore identical to the concentration of sunlight as defined herein.

The “active area” of a cell or cell stack is the area upon which photons can impinge and then be absorbed by the solar cell; i.e., the photovoltaic active front (i.e., light-facing) surface area of the cell.

The concentrating optical element preferably comprises a total internal reflecting concentrator that is a static concentrator. This static concentrator increases the power density of the solar light that can be utilized by the solar cell and will be a wide acceptance—angle concentrator that accepts light from a large portion of the sky. Unlike a tracking concentrator, a static concentrator is able to capture most of the diffuse light, much of which is in the blue to ultraviolet portion of the spectrum. This diffuse light makes up about 10% of the incident power in the solar spectrum. In practice, high levels of concentration are achieved by rejecting light from those portions of the sky in which the power density of the solar radiation is low throughout the year. In this way, concentrations of the solar light are increased by a factor of 10× or more. Higher concentrations are obtained if the position of the concentrator can be adjusted at some time during the year. Light is transmitted through one surface of the concentrator and that surface is adjacent to the surface of the dichroic mirror. “Solar light” is used herein to refer to the complete solar spectrum that impinges upon the surface of the dichroic mirror, no matter what the concentration. Preferably, the concentration is 10× or higher.

The light reflected and/or transmitted by the light separating means, preferably a dichroic mirror, will impinge upon the active surface of a cell, or the first (or top) cell in the appropriate cell stack, i.e., light with photons of energy≧E_{g} is directed to impinge upon the surface of a cell or (first cell in a cell stack) and light with photons of energy<E_{g} is directed to impinge upon the surface of a second cell (or first cell in a cell stack). This can be accomplished by directing the light directly onto the surfaces of the appropriate cells or cell stacks. Alternatively, a reflecting mirror can be positioned so that light reflected and/or transmitted by the dichroic mirror is reflected by the reflecting mirror and directed to impinge upon the surface of a cell, or the first cell in a cell stack. The dichroic mirror and the reflecting mirror can be incorporated in a single optical component.

Preferably, the overall solar cell comprises individual cells or cell stacks with different active surface areas. The use of different active surfaces areas leads to different levels of concentration of sunlight impinging upon the cells. Such variation in light concentration on a cell can result in alterations to the cell output and/or efficiency. Thus, use of different active surfaces areas provides the opportunity to select the concentrations of sunlight that result in optimum use of the cells and provide maximum output power for the module. Larger surface area cells reduce the decrease in output power resulting from beam walk, the tendency of the spot of light on the detector to move as the angle of the sun changes. Throughout, cost of the solar cell must be balanced against the power output.

The energy gaps of a respective cell or cell in a stack will depend upon the exact composition of such cell and the method of its preparation. Preferably, the energy gap of a GaInP cell is about 1.84 eV, the energy gap of a GaAs cell is about 1.43 eV, the energy gap of a Si cell is about 1.12 eV, the energy gap of a GaInAsP cell is in the range of from about 0.92 to about 0.95 eV, and the energy gap of a GaInAs cell is in the range of from about 0.69 eV to about 0.74 eV.

A cell stack can be a monolithic structure. Alternatively, some or all of the cells in a stack can be prepared on individual substrates. For example, in the case of a cell stack comprising Si, GaInAsP, and GaInAs cells, the Si cell can be prepared on a substrate that is transparent to the light transmitted by the Si cell and the GaInAsP and GaInAs cells can be prepared as a monolithic tandem.

In one embodiment, the cells and/or cell stacks within a solar cell are electrically connected in series to provide a single output. In a more preferred embodiment, some or preferably all of the individual cells and cells within a cell stack are contacted with individual electrical connections. This results in a substantial simplification of the solar cell and provides the opportunity to regulate the voltage across each cell at a value to provide optimum operation. The cells can be connected to a power combiner that provides a single electrical output for the solar cell at the desired voltage. Patent application WO2008/154031 “Power Converted and Power Combined for Power Limited Power Sources” and U.S. Ser. No. 12/496,941, PCT US2009/049480 “Method for Maximum Power Point Tracking of Photovoltaic Cells by Power Converters and Power Combiners” are specifically incorporated by reference herein in their entireties.

In a preferred embodiment, a GaInP cell with an energy gap of 1.84 eV and a GaAs cell with an energy gap of 1.43 eV are preferred cells for a first cell stack. A two cell stack consisting of a GaInP/GaAs tandem cell can be prepared using, trimethyl gallium, trimethyl indium, phosphine, arsine and other precursors as described by K. A. Bertness et al., Appl. Phys. Lett. 65, 989 (1994). These cells differ from conventional GaInP/GaAs cells because they transmit photons of energy less than their energy gaps. A two cell stack consisting of a GaInP/GaAs was made and was connected electrically in series. Such a cell stack with the best performance (fabricated by Emcore Corporation, Albuquerque, N. Mex.) had an active area of 0.1245 cm² and was operated at 25.1° C. and 20×. The open circuit voltage, V_{oc}, was 2.631 V and the short circuit current, I_{sc}, was 41.59 mA. The maximum power, Pₘₐₓ, was 95.46 mW with Vmax=2.334 V and Imax=40.90 mA. The tandem cell exhibited a fill factor (Pₘₐₓ/I_{sc}V_{oc}) of 87.24% and an efficiency of 31.7%.

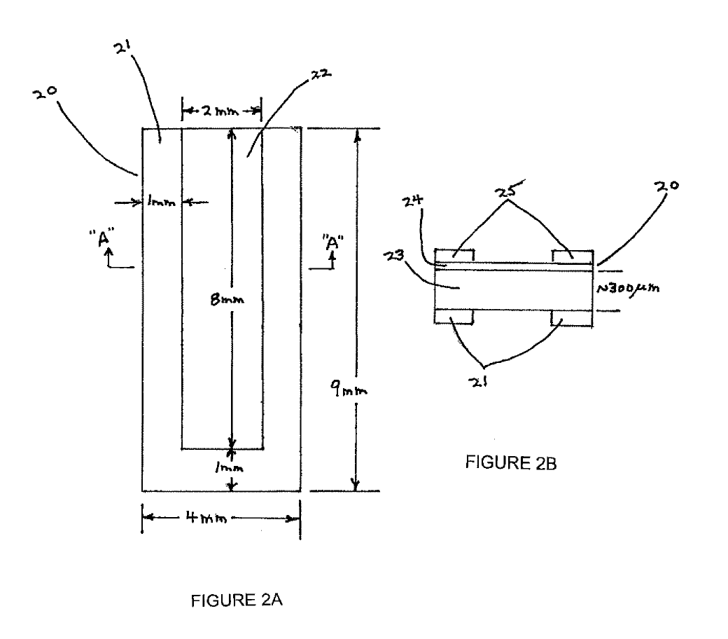

In a preferred embodiment, a second cell stack in a solar cell will have as its first cell in the stack a silicon cell with an energy gap of 1.12 eV. Recent innovations have provided the opportunity to provide high performance silicon cells at a low cost. These include the use of thinner silicon junctions, the passivation of silicon surfaces by means other than insulators (M. Taguchi et al., Progress in Photovoltaics: Research and Applications, Vol 8, p 503-513 (2000)), the use of an optically transparent substrate and demonstrated high minority carrier lifetimes in n-type silicon (A. Cuevas et al., Appl. Phys. Lett. 81, 4952 (2002)). Silicon cells were fabricated using the deposition of the wide-energy gap semiconductor amorphous silicon to passivate the surfaces and achieve higher voltages and efficiencies. See “Very High Efficiency Solar Cell Modules”, Progress in Photovoltaics, Research and Applications, 2009; 17:75-83, published online 1 Oct. 2008 (www.interscience.wiley.com) DOI: 10.1002/pip.852, which is incorporated by reference in its entirety. The structure used has a heterojuncton between crystalline silicon and amorphous silicon. The device performance is governed by the properties of the crystalline silicon substrate. The silicon cell design 20 is shown in FIGS. 2A and 2B. FIG. 2A is a bottom view. As shown the cell is 4 mm wide and 9 mm long. There is a 1 mm wide metallized band 21 around three edges of the cell. The active cell area 22 is 8 mm×2 mm. A cross-sectional view through “A-A” is shown in FIG. 2B. This view shows the metallized band 21 around the bottom of the silicon cell 23. A transparent conductive oxide, indium tin oxide, 24 is shown on the top of the silicon cell 23. A metallized band 25 on top of the indium tin oxide layer has the same dimensions and shape as metallized band 21. The metallized bands 21 and 25 provide contacts for the electrical connections. Keeping all the metallization outside the active area of the cell ensures maximum transmittivity to the cells below it. The cell dimensions are small enough to allow adequate conduction along the indium tin oxide and through the cell bulk with minimal resistance losses. The silicon cells were tested with solar light filtered through GaAs. This simulated the light with photons of energy<E_{g} that is directed to impinge upon the surface of the first cell in the second cell stack in the solar cell of the invention. The silicon cell with the best performance had an active area of 0.158 cm² and was operated at 25.0° C. plus or minus 1.0° C. When operated at 20× light (filtered by GaAs), the V_{oc} was 0.6900 V, I_{SC} was 37.10 mA, the maximum power, Pₘₐₓ, was 15.76 mW with Vmax=0.5084 V and Imax=31.00 mA, and the silicon cell exhibited a fill factor of 61.56% and an efficiency of 4.99%. When operated at 8.7× light (filtered by GaAs), the V_{Oc} was 0.6666 V, I_{SC} was 16.08 mA, Pₘₐₓ was 7.424 mW with Vmax=0.5272 V and Imax=14.08 mA, and the silicon cell exhibited a fill factor of 69.25% and an efficiency of 5.4%.

The second and third cells in the preferred second cell stack are preferably GaInAsP and GaInAs cells, which can be prepared as described by R. J. Wehrer et al., Conference Record, IEEE Photovoltaic Specialists Conference, 2002, p 884-887. The cells demonstrated were prepared as a monolithic tandem in which the two cells are connected electrically independently. Since the cells were not serially connected electrically, a tunnel junction was not included between the cells. This simplified the growth procedure. An attempt was made to lower the energy gaps of the two cells to realize slightly higher conversion efficiency. The energy gap of the GaInAsP cell was 0.92 eV and the energy gap of the GaInAs cell was 0.69 eV. The 3-terminal electrical connection enabled the measurement of the performance of each cell independently. The performance of the cells was measured under an idealized silicon filter (1100 nm cutoff). When the GaInAsP cell was under 21.4× light, the V_{OC} was 0.400 V, the short circuit current density, J_{sc}, was 281 mA/cm², and the cell exhibited a fill factor of 72% and an efficiency of 2.79%. When the GaInAs cell was under 28.9× light, the V_{oc} was 0.609 V, J_{sc} was 167 mA/cm², and the cell exhibited a fill factor of 73% and an efficiency of 3.46%. Thus, under these concentrations of light, the combined efficiency of the two cells was 6.2%. When the GaInAsP cell was under 40.1× light, the V_{oc} was 0.400 V, J_{sc} was 281 mA/cm², and the cell exhibited a fill factor of 71.9% and an efficiency of 1.94%. When the GaInAs cell was under 41.7× light, the V_{oc} was 0.628 V, J_{sc} was 314 mA/cm², and the cell exhibited a fill factor of 74.6% and an efficiency of 3.66%. Thus, under these concentrations of light, the combined efficiency of the two cells was 5.6%.

The total efficiency of the two demonstrated cell stack components was in the range of 42.3% to 43.3%.

The cell stacks can be mounted on one or more mounting boards depending on the configuration of the particular embodiment. A silicon cell that would serve as a scavenger cell to absorb light not otherwise absorbed and convert it into electricity can be placed adjacent to or contiguous to the last cell in one or both stacks. The silicon scavenger cell would have a larger cross-section than the cells in the cell stack, typically at least about 10 times that of the cells in the cell stack. See, for example, WO2008/091291, and WO2008/097266 which are incorporated by reference in their entireties. Some of the light intercepted by a scavenger cell is light that is not incident on the cell stack, reflected light, light not absorbed by cells in the stack, for example, by the cells in the first cell stack and diffuse light that did not impinge on the cell stacks. Scavenger silicon cells can be electrically connected in series or in parallel or connected independently.

Light reflected from the surfaces of cells is a potential source of decreased solar cell efficiency. An anti-reflection coating can be applied to the surfaces of any of the cells upon which light impinges to minimize this loss.

In one embodiment the light reflected and transmitted by the dichroic mirror propagates in air before impinging on the respective cell stacks. In another embodiment one or more transparent solids can be provided for these lights to propagate through.

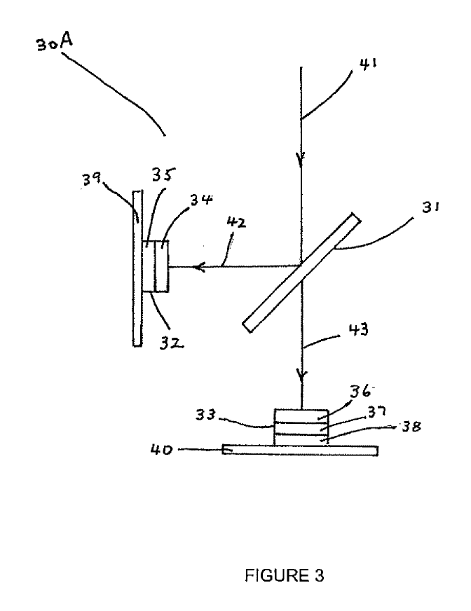

In FIGS. 3, 4, and 5, the same numbers are used to identify the same entities. For, simplicity, the various light beams are represented by one light ray.

FIG. 3 illustrates an embodiment of the hybrid solar cell. The solar cell 30A is comprised of “cold” dichroic mirror 31, a first cell stack 32 and a second cell stack 33. The first cell stack 32 contains two cells, a GaInP cell 34 and a GaAs cell 35. The second cell stack 33 contains three cells, a Si cell 36, a GaInAsP cell 37 and a GaInAs 38. The dichroic mirror 31 operates at E_{g} and reflects light with photons of energy≧E_{g} and transmits light with photons of energy<E_{g}. Solar light 41 impinges upon the dichroic mirror 31 which is positioned at an angle of about 45° with respect to the direction of the solar light 41. Light 42 with photons of energy≧E_{g} is reflected by the dichroic mirror and impinges upon the surface of the first cell 34 of the first cell stack 32. Cells 34 and 35 each absorb light with photons of energy greater than or equal to their energy gap and are transparent to and transmit light with photons of energy less than their energy gap. Light 43 with photons of energy<E_{g} is transmitted by the dichroic mirror and impinges upon the surface of the first cell 36 of the second cell stack 33. Cells 36, 37 and 38 each absorb light with photons of energy greater than or equal to their energy gap and are transparent to and transmit light with photons of energy less than their energy gap. FIG. 3 shows an embodiment in which the hybrid solar cell further comprises Si scavenger cells 39 and 40. Si scavenger cell 39 is shown contiguous to cell 35 and Si scavenger cell 40 is shown contiguous to cell 38. Light in their respective areas which does not impinge on the first cell stack 33 and the second cell stack 34 impinges on the Si scavenger cells 39 and 40.

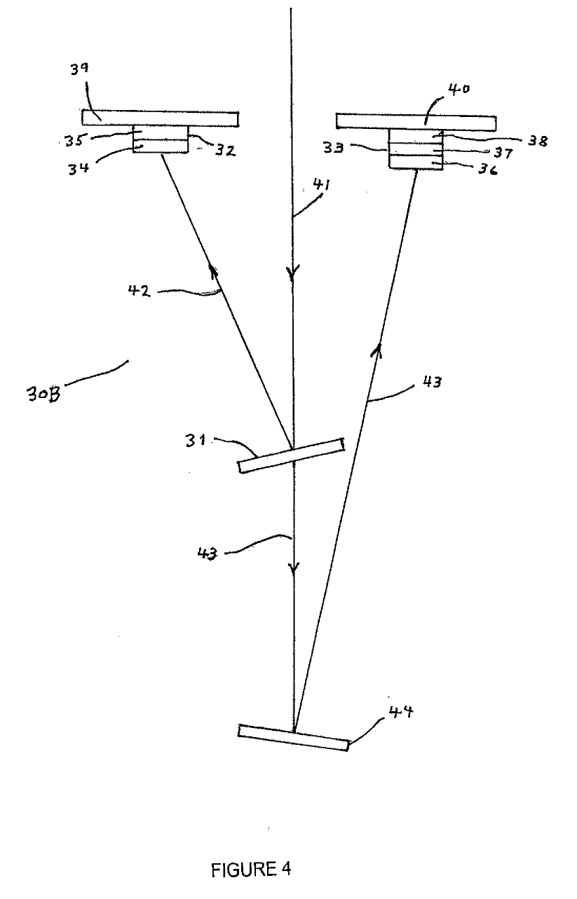

FIG. 4 illustrates another embodiment of the hybrid solar cell. The solar cell 30B is comprised of “cold” dichroic mirror 31, a first cell stack 32, a second cell stack 33 and a reflecting mirror 44. The first cell stack 32 contains two cells, a GaInP cell 34 and a GaAs cell 35. The second cell stack 33 contains three cells, a Si cell 36, a GaInAsP cell 37 and a GaInAs 38. The dichroic mirror 31 operates at E_{g} and reflects light with photons of energy E_{g} and transmits light with photons of energy<E_{g}. Solar light 41 impinges upon the dichroic mirror 31 which is positioned so that light is reflected as shown in FIG. 4. Light 42 with photons of energy≧E_{g} is reflected by the dichroic mirror and impinges upon the surface of the first cell 34 of the first cell stack 32. Cells 34 and 35 each absorb light with photons of energy greater than or equal to their energy gap and are transparent to and transmit light with photons of energy less than their energy gap. Light 43 with photons of energy<E_{g} is transmitted by the dichroic mirror and is reflected by the reflecting mirror 44. The reflected light 43 impinges upon the surface of the first cell 36 of the second cell stack 33. Cells 36, 37 and 38 each absorb light with photons of energy greater than or equal to their energy gap and are transparent to and transmit light with photons of energy less than their energy gap. FIG. 4 shows an embodiment in which the hybrid solar cell further comprises Si scavenger cells 39 and 40. Si scavenger cell 39 is shown contiguous to cell 35 and Si scavenger cell 40 is shown contiguous to cell 38. Light in their respective areas which does not impinge on the first cell stack 33 and the second cell stack 34 impinges on the Si scavenger cells 39 and 40. In this configuration the cell stacks and the Si scavenger cells can readily be supported on the same mounting board.

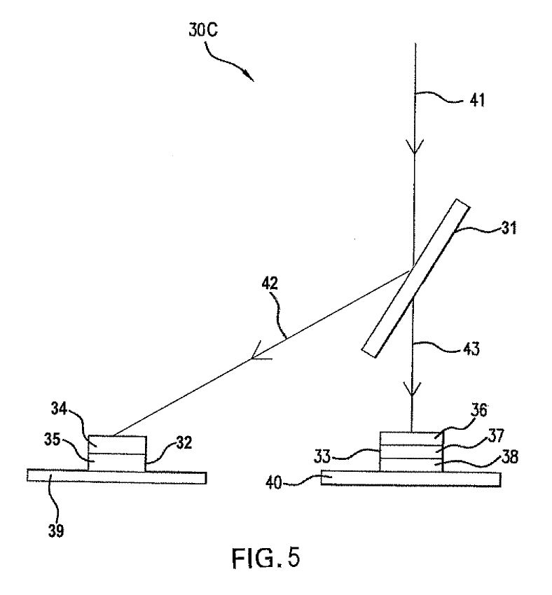

FIG. 5 illustrates yet another embodiment of the hybrid solar cell. The solar cell 30C is comprised of “cold” dichroic mirror 31, a first cell stack 32 and a second cell stack 33. The first cell stack 32 contains two cells, a GaInP cell 34 and a GaAs cell 35. The second cell stack 33 contains three cells, a Si cell 36, a GaInAsP cell 37 and a GaInAs 38. The dichroic mirror 31 operates at E_{g} and reflects light with photons of energy E_{g} and transmits light with photons of energy<E_{g}. Solar light 41 impinges upon the dichroic mirror 31 which is positioned so that light is reflected as shown in FIG. 5. Preferably, the angle of dichroic mirror 31 is about 10-35° with respect to the direction of the solar light 41. Light 42 with photons of energy≧E_{g} is reflected by the dichroic mirror and impinges upon the surface of the first cell 34 of the first cell stack 32. Cells 34 and 35 each absorb light with photons of energy greater than or equal to their energy gap and are transparent to and transmit light with photons of energy less than their energy gap. Light 43 with photons of energy<E_{g} is transmitted by the dichroic mirror and impinges upon the surface of the first cell 36 of the second cell stack 33. Cells 36, 37 and 38 each absorb light with photons of energy greater than or equal to their energy gap and are transparent to and transmit light with photons of energy less than their energy gap. FIG. 5 shows an embodiment in which the hybrid solar cell further comprises Si scavenger cells 39 and 40. Si scavenger cell 39 is shown contiguous to cell 35 and Si scavenger cell 40 is shown contiguous to cell 38. Light in their respective areas which does not impinge on the first cell stack 33 and the second cell stack 34 impinges on the Si scavenger cells 39 and 40. In this configuration the cell stacks and the Si scavenger cells can readily be supported on the same mounting board. In a further preferred embodiment, solar light 41 is concentrated by a static concentrating optical element before impinging onto the dichroic mirror 31.

What is claimed is:

1. A high efficiency hybrid solar cell comprising
(a) a means for separating light into more than one spectral component based upon energy of the photons of light, and
(b) more than one individual cells or cell stacks, at least one of which is a cell stack.

2. The solar cell of claim 1, further comprising a static concentrating optical element that concentrates light impinging onto the light separating means.

3. The solar cell of claim 1, wherein the means for separating light comprises a dichroic mirror.

4. The solar cell of claim 1, wherein the more than one individual cell or cell stack have different active cell surface areas.

5. A high efficiency hybrid solar cell comprising
(a) a dichroic mirror operating at E_{g} and positioned so that solar light impinges upon the dichroic mirror, wherein the dichroic mirror provides a separation of the solar light into two spectral components, one component of light with photons of energy≧E_{g} and one component of light with photons of energy<E_{g}, wherein one of these components is reflected by the dichroic mirror and one is transmitted by the dichroic mirror;
(b) a first cell stack comprising two cells, the first cell being a GaInP cell and the second cell being a GaAs cell, arranged vertically in descending order of their energy gaps with the first cell having the larger energy gap of the cells in the first cell stack, the first cell stack being positioned so that the component of light with photons of energy≧E_{g} impinges upon the surface of the first cell in the first cell stack, wherein the cells in the first cell stack each absorb light with photons of energy greater than or equal to their energy gap and are transparent to and transmit light with photons of energy less than their energy gap, wherein E_{g} is equal to about the energy gap of the GaAs cell; and
(c) a second cell stack comprising three cells, the first cell being a silicon cell, the second cell being a GaInAsP cell and the third cell being a GaInAs cell, arranged vertically in descending order of their energy gaps with the first cell having the largest energy gap of the cells in the second cell stack, the second cell stack being positioned so that the component of light with photons of energy<E_{g} impinges upon the surface of the first cell in the second cell stack, wherein the energy gap of each cell in the second cell stack is <E_{g} and wherein cells in the second cell stack each absorb light with photons of energy greater than or equal to their energy gap and are transparent to and transmit light with photons of energy less than their energy gap.

6. The high efficiency hybrid solar cell of claim 5, further comprising a static concentrating optical element that directs solar light to the dichroic mirror (a).

7. The high efficiency hybrid solar cell of claim 5, wherein the dichroic mirror reflects light with photons of energy≧E_{g} and transmits light with photons of energy<E_{g}.

8. The high efficiency hybrid solar cell of claim 5, wherein the energy gap of the GaInP cell is about 1.84 eV, the energy gap of the GaAs cell is about 1.43 eV, the energy gap of the Si cell is about 1.12 eV, the energy gap of the GaInAsP cell is in the range of from about 0.92 to about 0.95 eV and the energy gap of the GaInAs cell is in the range of from about 0.69 eV to about 0.74 eV.

9. The high efficiency hybrid solar cell of claim 7, wherein E_{g} is about 1.43 eV.

10. A method for converting solar light into electrical power, the method comprising:
(a) positioning a dichroic mirror so that solar light impinges onto the surface of the dichroic mirror and the dichroic mirror separates the light into two spectral components of light, one component of light with photons of energy≧E_{g} and one component of light with photons of energy<E_{g};
(b) positioning a first cell stack comprising two cells, the first cell being a GaInP cell and the second cell being a GaAs cell, arranged vertically in descending order of their energy gaps with the first cell having the larger energy gap of the cells in the first cell stack, the first cell stack being positioned so that the component of light with photons of energy≧E_{g} impinges upon the surface of the first cell in the first cell stack, wherein the cells in the first cell stack each absorb light with photons of energy greater than or equal to their energy gap and are transparent to and transmit light with photons of energy less than their energy gap, wherein E_{g} is equal to about the energy gap of the GaAs cell; and
(c) positioning a second cell stack comprising three cells, the first cell being a Si cell, the second cell being a GaInAsP cell and the third cell being a GaInAs cell, arranged vertically in descending order of their energy gaps with the first cell having the largest energy gap of the cells in the second cell stack, the second cell stack being positioned so that the component of light with photons of energy<E_{g} impinges upon the surface of the first cell in the second cell stack, wherein the energy gap of each cell in the second cell stack is <E_{g} and wherein cells in the second cell stack each absorb light with photons of energy greater than or equal to their energy gap and are transparent to and transmit light with photons of energy less than their energy gap.

11. The method of claim 10, wherein the dichroic mirror reflects light with photons of energy≧E_{g} and transmits light with photons of energy<E_{g}.

12. The method of claim 11, wherein the energy gap of the GaInP cell is about 1.84 eV, the energy gap of the GaAs cell is about 1.43 eV, the energy gap of the Si cell is about 1.12 eV, the energy gap of the GaInAsP cell is in the range of from about 0.92 to about 0.95 eV and the energy gap of the GaInAs cell is in the range of from about 0.69 eV to about 0.74 eV. and E_{g} is about 1.43 eV.

13. The method of claim 10, wherein the first cell stack and the second cell stack have different active cell surface areas.
